(19) United States
(12) Patent Application Publication
(10) Pub. No.: US 2010/0120248 A1
(43) Pub. Date: May 13, 2010

(54) ETCHING SOLUTION AND ETCHING METHOD

(75) Inventors: Peter Fath, Konstanz (DE); Ihor Melnyk, Konstanz (DE)

Correspondence Address: LERNER GREENBERG STEMER LLP, P O BOX 2480, HOLLYWOOD, FL, 33022-2480, US

(73) Assignee: GP SOLAR GMBH, Konstanz (DE)

(21) Appl. No.: 12/524,016

(22) PCT Filed: Jan. 22, 2008
(86) PCT No.: PCT/DE08/00099

§ 371 Date: Jan. 20, 2010

(30) Foreign Application Priority Data
Jan. 22, 2007 (DE) 10 2007 004 060.3

(51) Int. Cl. C09K 13/04; H01L 21/461

(52) U.S. Cl. 438/692; 252/79.2; 257/E21.483

(57) ABSTRACT

An etching solution contains water, nitric acid, hydrofluoric acid, and sulphuric acid. More specifically it contains 15 to 40% by weight of nitric acid, 10 to 41% by weight of sulphuric acid and 0.8 to 2.0% by weight of hydrofluoric acid. The etching solution is used for etching silicon and to etching methods for silicon wafers.

The invention relates to an etching solution in accordance with the preamble of claim 1, to the use of said etching solution for etching silicon, and to an etching method in accordance with the preamble of claim 12.

Semiconductor components play a major part in many branches of technology. In accordance with the diversity of different components, a wide variety of requirements are made of the technologies for processing this material. Among these, etching technologies and etching methods have acquired great importance. This is due to the fact that, with the aid thereof, firstly the material can be selectively processed at individual locations, and secondly it is possible to process large numbers, in particular on an industrial scale. Most semiconductor components fabricated at the present time are based on silicon as starting material.

During the selective processing of individual locations of the components or blanks it must be ensured that the etching solution only reaches those locations at which material is intended to be removed, but other regions will be unaffected. This is usually done by regions that are not to be etched being covered, masked as it were, with a material that is resistant to the etching solution. Such masking can be effected by applying etching-solution-resistant resists, films, sheets or the like. Such maskings are complicated. If possible, therefore, recourse is had to other effects in order to protect individual regions from contact with the etching solution, for example to wetting phenomena or the effect of gravitation. In the simplest case, a blank is only partly held into an etching solution that does not completely wet it, with the result that the blank is etched below the liquid level of the etching solution and below the wetted regions of the blank, but is not etched above the wetted regions.

The extent to which a selective processing of individual regions can be achieved solely by partly dipping the blank into the etching solution, without other regions being detrimentally affected, depends on the individual case. In particular, surface structures, on account of capillary effects, can have the consequence that etching solution reaches regions at which no etching process is intended.

Therefore, the present invention is based on the object of providing an improved etching solution which enables more precise selective processing of individual regions.

This object is achieved according to the invention by means of an etching solution comprising the features of claim 1.

Furthermore, the invention is based on the object of improving the etching of silicon, in particular of silicon wafers with a surface structuring.

This object is achieved by means of the use according to the invention of the etching solution in accordance with claim 5.

Moreover, the invention is based on the object of providing an improved etching method for silicon wafers.

This object is achieved by means of an etching method comprising the features of claim 12.

Dependent subclaims respectively relate to advantageous developments.

The etching solution according to the invention has a comparatively low surface tension in conjunction with a good etching effect in the case of inorganic materials, in particular in the case of silicon. Consequently, it has a reduced tendency to penetrate into small-dimensioned surface structures. Such surface structures can be formed by microcracks or processing structures in the surface of the blank to be etched. Moreover, it is also possible in part to introduce surface structurings—often also referred to as surface texturings—into the blank. Such surface structurings can be introduced mechanically, for example, such as occurs in particular during the mechanical structuring of solar cells for the purpose of increasing the coupling-in of light. However, they can also be the consequence of a preceding etching process. By way of example, anisotropic etching solutions are used in turn in the field of solar cell fabrication, which etching solutions have etching effects of different magnitudes in different spatial directions, if appropriate depending on the crystal orientation of a crystal to be etched, with the result that a surface structure is formed. Said surface structure can in turn bring about an increased coupling-in of light into the solar cells.

Penetration of the etching solution into said structures would damage the surface structuring. This risk is significantly reduced, however, in the case of the etching solution according to the invention. Consequently, the regions without surface structuring can be brought into contact with the etching solution and etched without the regions with a surface structure being damaged in the process.

Preferably, the etching solution according to the invention is used for, if appropriate selectively, etching silicon or silicon-containing compounds, in particular silicate glasses. This should also be understood to include doped silicon. Moreover, an application in the field of other non-organic materials, in particular semiconductor materials, is also conceivable.

In the case of etching silicon, but also other semiconductor materials, the sulfuric acid in the etching solution according to the invention does not participate in the chemical etching reaction. It primarily serves to increase the specific density of the etching solution. As a result of the chemical reactions proceeding during the etching process and the associated conversion of the reagents, although the specific density of the etching solution decreases per se, this is approximately compensated for by the etched-away silicon now situated in the etching solution. Consequently, it is not necessary to supply sulfuric acid for maintaining the initial specific density.

The etching solution according to the invention can advantageously be used in particular in the field of silicon semiconductor technology. In this branch of technology, dopants are indiffused into silicon wafers, with silicate glasses being formed, which often have to be removed. This can be effected by means of the etching solution according to the invention. Boro- or phosphosilicate glasses produced during phosphorus or boron diffusions can be removed, inter alia. In addition, doped layers can be removed locally with at the same time a low risk of damage for the surrounding doped regions.

In the abovementioned branch of silicon semiconductor technology, silicon wafers are usually used as starting material for the production of the semiconductor components such as integrated circuits or solar cells. They are largely produced by sawing cast silicon blocks into wafers or sawing off wafers from pulled silicon columns. During these sawing processes, which are usually carried out by means of wire saws, the surface of the silicon wafers is damaged. This is normally removed by overetching the silicon wafers, in which case the etching solution according to the invention can likewise be used.

In addition, in other methods, silicon wafers are pulled from a silicon melt directly with the desired thickness. These silicon wafers are often referred to as silicon ribbons. In the case of the latter, although sawing damage in the sense explained is not present, the layer near the surface is often relatively highly contaminated, with the result that an overetching of the silicon wafers is performed here for the purpose of at least partly removing these contaminated layers. The etching solution according to the invention can once again be employed in this case.

The invention is explained in more detail below on the basis of an exemplary embodiment illustrated in figures, in which:

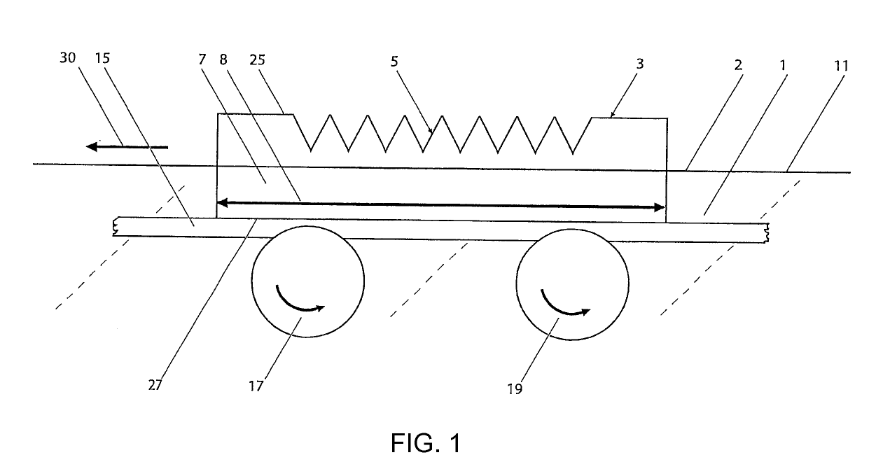

FIG. 1 shows a schematic illustration of a silicon wafer provided with a surface structuring in an etching solution according to the invention during the etching according to an etching method according to the invention in a side view.

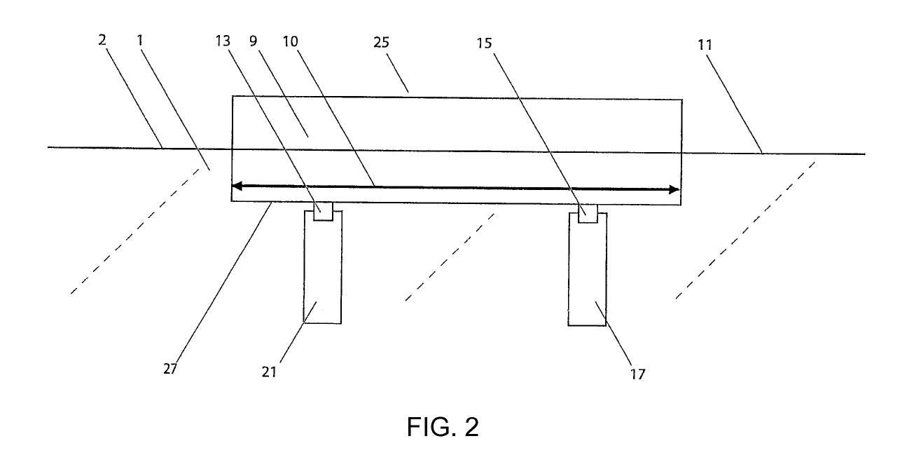

FIG. 2 shows a front view of the silicon wafer from FIG. 1.

FIG. 1 shows a silicon wafer 3 provided for fabricating a solar cell, which silicon wafer has already been subjected to a phosphorus diffusion. Consequently, it bears a phosphorus-doped layer and a phosphosilicate glass over its entire surface. Furthermore, the silicon wafer was provided with a surface structuring 5 prior to the phosphorus diffusion. Said surface structuring was introduced mechanically in the present case. However, the way in which the surface structure is introduced is unimportant for the invention. This can for example also be effected by chemical methods such as anisotropic etching methods or etching methods that act in a manner dependent on crystal orientation.

The two side areas of the silicon wafer 3 that have the largest area form the front side 25 and the rear side 27. In addition, the silicon wafer 3 peripherally has edge areas 7, 9, of which the edge area 7 can be seen in FIG. 1. Each of the edge areas has a longitudinal extension 8 or 10, respectively.

The silicon wafer 3 is partly dipped into an etching solution 1. In this case, the dipping depth is chosen such that each edge area, in particular the edge areas and 9, along the direction of the longitudinal extension thereof, along the direction of the longitudinal extensions 8 and 10 in the case of the edge areas 7 and 9, are always situated partly below the liquid level 11 of the etching solution. In this way it is possible to remove the phosphosilicate glass and the phosphorus-doped layer situated underneath at the edge areas such that when a conductive layer is applied to the rear side 27 of the solar cell, there is no electrically conductive connection to the front side via the edge areas, which would short-circuit the solar cell. Moreover, it is possible to remove the phosphorus-doped layer and the phosphorus glass on the rear side 27.

The etching solution used is an etching solution 1 according to the invention comprising water, nitric acid, hydrofluoric acid and sulfuric acid, which contains 15 to 40 percent by weight of nitric acid, 10 to 41 percent by weight of sulfuric acid and 0.8 to 2.0 percent by weight of hydrofluoric acid. An etching solution 1 containing 27 percent by weight of nitric acid, 26 percent by weight of sulfuric acid and 1.4 percent by weight of hydrofluoric acid is preferably used. Furthermore, deionized water is used in the present case in order to prevent an introduction of contamination into the silicon wafer 3, which could impair the performance of the finished solar cell. With less stringent purity requirements, water in a generally available form can be used instead.

During the etching the etching solution 1 is always held at a temperature of between 4° C. and 15° C., preferably at a temperature of between 7° C. and 10° C. This makes it possible, in conjunction with the etching solution 1 according to the invention, for said etching solution not to pass into and damage parts of the surface structuring 5 on account of capillary effects (explained above).

This is of importance particularly when thin silicon wafers 3 are intended to be etched. Otherwise, it is possible to maintain enough distance between the liquid level 11 of the etching solution 1 and the lower edge of the surface structuring 5 during the etching process, such that the risk of damage to the surface structuring is low. However, semiconductor components are normally made thin. In the case of solar cells for example, the thickness, that is to say the distance between front side 25 and rear side 27 of the silicon wafer 3 is usually in the range of 100 nm to 350 nm with a trend to more extensive reduction of the thickness. In these thickness ranges it is of crucial importance to prevent penetration of etching solution 1 into the surface structuring 5 by capillary effects, since the liquid level 11 of necessity is situated only slightly below the lower edge of the surface structuring 5, if it is to be ensured that the edge areas 7 and 9, along the direction of the longitudinal extensions 8 and 10, are always situated partly below the liquid level 11 of the etching solution 1.

Such restrictions are also found in the production of other semiconductor components, in particular those composed of silicon such as silicon-based integrated circuits or nanomachines such as e.g. nanomotors or nanopumps. Consequently, the invention can likewise be used beneficially there.

In the exemplary embodiment in FIGS. 1 and 2, the dipping depth of the silicon wafer is determined by the conveyor belts 13 and 15 which are illustrated in FIGS. 1 and 2 and on which the silicon wafer 3 bears. Instead of the latter, other devices on which the silicon wafer 3 bears, for example lowerable wire grids or the like, are also conceivable, of course. The advantage of the conveyor belts 13 and 15, the number of which can be chosen as desired, in principle, depending on the mechanical properties of the silicon wafer 3, is that they can be driven comparatively simply, by means of drive rollers 17, 19, 21 for example. This enables silicon wafers 3 to be etched in an efficient continuous method. The silicon wafers 3 are placed onto the driven conveyor belts 13 and 15 and transported through the etching solution at a defined dipping depth parallel to the surface 2 of said etching solution before they are fed to further process units.

Instead of conveyor belts 13, 15, it is also possible, in a known manner, to provide transport rollers which are arranged in a continuous sequence and which transport the silicon wafer through the etching solution 1 and enable a continuous method. In the case of semiconductor components that can be subjected to less mechanical loading, however, conveyor belts that are elastic to a certain extent may be more advantageous.

### LIST OF REFERENCE SYMBOLS

1 Etching solution
2 Surface of etching solution
3 Phosphorus-doped silicon wafer with phosphosilicate glass
5 Surface structuring
7 Edge area
8 Longitudinal extension of edge area
9 Edge area
10 Longitudinal extension of edge area
11 Liquid level of etching solution
13 Conveyor belt
15 Conveyor belt
17 Drive roller
19 Drive roller
21 Drive roller
25 Front side of silicon wafer
27 Rear side of silicon wafer
30 Direction of movement of the silicon wafer

1-22. (canceled)

23. An etching solution, comprising:
15 to 40 percent by weight of nitric acid;
10 to 41 percent by weight of sulfuric acid;
0.8 to 2.0 percent by weight of hydrofluoric acid; and
remainder water.

24. The etching solution according to claim 23, wherein:
said nitric acid is 20 to 30 percent by weight;
said sulfuric acid is 18 to 35 percent by weight; and
said hydrofluoric acid is 1.0 to 1.7 percent by weight.

25. The etching solution according to claim 23, wherein:
27 percent by weight of said nitric acid;
26 percent by weight of said sulfuric acid; and
1.4 percent by weight of said hydrofluoric acid.

26. The etching solution according to claim 23, wherein said water is at least partly deionized.

27. An etching method, which comprises the steps of:
providing an etching solution containing 15 to 40 percent by weight of nitric acid, 10 to 41 percent by weight of sulfuric acid, 0.8 to 2.0 percent by weight of hydrofluoric acid, and remainder water; and
etching silicon, including doped silicon, silicon-containing compounds, and silicate glasses with the etching solution.

28. The method according to claim 27, which further comprises etching one of phospho- and borosilicate glass with the etching solution.

29. The method according to claim 27, which further comprises using the etching solution for at least partly overetching silicon wafers, including doped silicon wafers.

30. The method according to claim 29, which further comprises using the etching solution for etching silicon-containing compounds, including silicate glasses, present on the silicon wafers.

31. The method according to claim 29, wherein the silicon wafers have at least partly a surface structuring including mechanical structurings or chemical surface structurings.

32. The method according to claim 29, which further comprises using the etching solution for overetching edge areas of the silicon wafers.

33. The method according to claim 29, wherein the silicon wafers are for producing solar cells into which a dopant has been indiffused, and the etching solution is used for at last partly removing regions doped by the diffusion, including for insulating edge areas of the silicon wafers.

34. An etching method for silicon wafers for partly removing silicon, including doped silicon, silicon-containing compounds, and silicate glasses, which comprises the step of:
bringing at least one part of each individual silicon wafer into contact with an etching solution, the etching solution is held at a temperature of between 4° C. and 15° C., the etching solution containing:
15 to 40 percent by weight of nitric acid;
10 to 41 percent by weight of sulfuric acid;
0.8 to 2.0 percent by weight of hydrofluoric acid; and
remainder water.

35. The etching method according to claim 34, which further comprises partly dipping the silicon wafers into the etching solution.

36. The etching method according to claim 35, which further comprises partly dipping the silicon wafers having a surface structure into the etching solution such that the surface structure lies above a liquid level of the etching solution.

37. The etching method according to claim 36, which further comprises moving the silicon wafers in a dipped position parallel to a surface of the etching solution.

38. The etching method according to claim 37, which further comprises moving the silicon wafers on one of rollers and conveyor belts parallel to the surface of the etching solution.

39. The etching method according to claim 35, which further comprises dipping the silicon wafers into the etching solution such that of two sides of each silicon wafer which have a largest area, one is situated below a liquid level of the etching solution and one is situated above the liquid level of the etching solution.

40. The etching method according to claim 39, which further comprises dipping the silicon wafers into the etching solution such that each of edge areas of the silicon wafer, along a longitudinal extension direction thereof, are always situated at least partly below the liquid level of the etching solution.

41. The etching method according to claim 34, which further comprises holding the etching solution at a temperature of between 7° C. and 10° C.

42. The etching method according to claim 34, which further comprises etching the silicon wafers into which a dopant has been indiffused and doped regions of the silicon wafers are at least partly removed during the etching.

43. The etching method according to claim 34, which further comprises etching the silicon wafers into which a dopant has been indiffused and silicate glasses, including phospho- or borosilicate glasses, formed during diffusion are at least partly removed during the etching.

44. The etching method according to claim 34, which further comprises etching the silicon wafers in a continuous method.
